(19) United States
(12) Patent Application Publication
(10) Pub. No.: US 2026/0223387 A1
(43) Pub. Date: Jul. 30, 2026

(54) MICROELECTRONIC DEVICE COMPRISING A WRAPPING GRID AND METHOD OF PRODUCTION

(71) Applicant: COMMISSARIAT A L'ENERGIE ATOMIQUE ET AUX ENERGIES ALTERNATIVES, Paris (FR)

(72) Inventors: Sylvain BARRAUD, Grenoble Cedex 09 (FR); Rihab CHOUK, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/325,672

(22) Filed: Sep. 11, 2025

(30) Foreign Application Priority Data
Sep. 12, 2024 (FR) FR2409722

(51) Int. Cl. H10D 30/00; H10D 30/01

(52) U.S. Cl. CPC H10D 30/501; H10D 30/019

(57) ABSTRACT

A device comprising channels stacked along a direction, a gate-all-around, totally surrounding several channels, a source and a drain on either side of each channel, and source and drain contacts. Advantageously, the source and drain contacts respectively form a first comb and a second comb opposite one another, separated by dielectric plugs, the electric contact between the fingers of each of the combs and the sources and/or the drains being made along the direction.

### TECHNICAL FIELD

The invention relates to the field of microelectronics technologies. It has a particularly advantageous application in manufacturing FET (Field-Effect Transistor)-type gate-all-around advanced devices with a two-dimensional (2D) material- or semiconductor oxide-based channel.

### PRIOR ART

The constant increasing of performance of transistors has first been enabled by reducing dimensions of transistors, for a silicon-based conventional MOSFET (Metal-Oxide-Semiconductor Field-Effect Transistor) architecture.

This conventional architecture has then been replaced by other types of architectures which are best adapted to the performance specified in technological nodes less than 12 nm. The so-called “finFET” architecture makes it possible, for example, to respond to the performance set by the 7 nm technological node.

For future technological nodes, in particular from 2 nm, other architectures offering an improved gate confinement are necessary. An architecture considered to respond to the problems of these future technological nodes comprises gate-all-around transistors called GAA transistors, stacked on one another.

In parallel to developing novel architectures, materials other than silicon are considered for manufacturing transistor channels. Recently, 2D materials, which can be constituted of one single atom layer, have appeared as promising candidates for a use in electronic and optoelectronic devices comprising one or more very thin elements.

Document US2023/0093343 discloses a method for manufacturing superposed GAA transistors, comprising a 2D material-based channel. In this method, the 2D materials considered are, in particular, transition metal dichalcogenides in the form of monolayers. These 2D materials degrade easily when they are subjected to the typical conditions of deposition and etching methods. Yet, the different steps of the method disclosed by this document involve such conditions, able to degrade the 2D material monolayers. It also appears that the drain and source contacts obtained by this method are not very reliable and/or not very efficient. Slightly resistive drain and source contacts are difficult to produce on 2D materials.

An efficient architecture and a reliable industrial manufacture, satisfying the required quality requirements, are significant challenges for developing 2D material-based GAA transistor technologies.

An aim of the invention is to propose a device and a manufacturing method responding to these challenges. Another aim of the invention is to overcome at least partially the disadvantages of known methods.

### SUMMARY

To achieve these aims, according to an embodiment, a microelectronic device is provided, comprising:
at least two channels stacked along a main direction z, each channel being with the basis of a semiconductor material,
a so-called gate-all-around, surrounding at least one of the channels over an entire perimeter of said channel, and preferably several channels,
a source and a drain on either side of each channel, and source and drain contacts connected respectively to the source and to the drain,
a gate dielectric layer separating each channel and the gate-all-around,
spacers on either side of the gate, configured to electrically insulate the gate opposite the source and drain contacts.

Advantageously, the source and drain contacts each comprise a so-called main part extending along the main direction z, and secondary parts connected to the main part and extending along a sequent direction x to the main direction z, and extending at least partially in vertical alignment with the spacers flanking the gate-all-around, such that the main part and the secondary parts of the source contact form a first comb and the main part and the secondary parts of the drain contact form a second comb opposite the first comb, along the sequent direction x. The sequent direction x is, for example, transverse or perpendicular to the main direction z.

Thus, the source and drain contacts advance under the spacers flanking the gate-all-around. The sources and the drains also advance under the spacers flanking the gate-all-around, superposing the source and drain contacts, along the main direction z. This makes it possible to avoid that the contact is done only “by the side” of the sources and of the drains. The secondary parts of the source contact, i.e. the fingers of the first comb, are typically inserted between two sources stacked successively along the main direction z. In the same way, the secondary parts of the drain contact, i.e. the fingers of the second comb, are typically inserted between two drains stacked successively along the main direction z. The quality of the source/drain contact is improved. The sources and the drains extend each typically in vertical alignment with the spacers. This structural feature makes it possible to maximise the surface between the source contact and the source on the one hand, and the drain contact and the drain on the other hand. The resistance of access to the sources and to the drains of the device is thus significantly decreased.

The secondary parts extend between the sources and the drains, respectively, further reduce the effective gate length Lg for the stacked channels. This makes it possible to improve the transistor features of the device. The device can, in particular, operate with a stronger current. It is thus possible to physically modulate, by the effective gate length Lg, the figures of merit of the device, in particular, the lon/loff ratio of the drain currents in the on state and in the off state. This modulation can be done locally, on certain zones of a microelectronic chip comprising a plurality of devices according to the invention.

Another aspect of the invention relates to a method for manufacturing such a device, the method comprising:
Providing, on a substrate S, a stack E along the main direction z comprising first layers made of a first material alternated with second layers made of a second material, the first and second materials being different from the semiconductor material of the channels of the device,
Forming, in this stack E, first openings defining first patterns,
Forming sacrificial gates mounted on the first patterns and partially in the first openings,
Forming first spacers on the first patterns and bordering the sacrificial gates,
Forming, in the first patterns, second openings defining second patterns,
Partially removing, from the second openings, the first material of the first layers selectively at the second material of the second layers, so as to form first spaces under the first spacers, and preferably partially under the sacrificial gates,
Filling the first spaces with a dielectric material to form internal spacers,
Totally removing, from the second openings, the second material of the second layers, so as to form second spaces,
Depositing a layer with the basis of a semiconductor material on exposed surfaces of the second spaces, without totally filling the second spaces, said layer being intended to form the semiconductor material-based channels, and the semiconductor material-based sources and drains,
Filling the second spaces with a dielectric material, so as to form dielectric plugs occupying the second spaces,
Partially etching the dielectric plugs from the second openings, on either side of the second patterns, so as to reduce a dimension l₇₀ of said dielectric plugs along the sequent direction x, the second spaces being obstructed in their centres by the dielectric plugs,
Filling the second spaces and the second openings with a metal material, so as to form the source and drain contacts in the form of first and second combs opposite one another,
Removing the sacrificial gates, so as to form third openings,
Totally removing, from the third openings, the first material of the remaining parts of the first layers, so as to form third spaces,
Forming a dielectric layer, called gate dielectric layer, in the third spaces,
Filling with a material, called gate material, the third spaces, so as to form the gates-all-around.

Thus, the semiconductor material-based layer has a thickness less than that of the second layers of the initial stack.

The partial etching of the dielectric plugs subsequently makes it possible to form the fingers of the first and second combs, in the second spaces left vacant. The fingers of the first and second combs can extend in this way along the sequent direction x, under the sources and drains, respectively. According to an option, stopping the partial etching is controlled at the time. Advantageously, the partial etching is configured, so as to significantly reduce the dimension l₇₀ along the sequent direction x of the dielectric plugs. The final dimension l₇₀ of the dielectric plugs, after partial etching, is preferably less than at least 80% of the initial dimension l₇₀ of the dielectric plugs, before partial etching. The control at the time of stopping etching is thus facilitated. This makes it possible to improve the dimensional control of the dielectric plugs. The final dimension l₇₀ of the dielectric plugs conditions the effective gate length Lg of the device. The dimensional control of the effective gate length Lg is also improved.

It is possible to configure different partial etching times on different zones of one same chip. This makes it possible to ultimately form devices having physically different effective gate lengths Lg.

The other aims, features and advantages of the present invention will appear upon examining the description below and the accompanying drawings. It is understood that other advantages can be incorporated.

### BRIEF DESCRIPTION OF THE FIGURES

FIGS. 1A, 2A, 3A, 4A, 5A, 6A, 7A, 8A, 9A, 10A, 11A, 12A, 13A, 14A, and 15A schematically illustrate along transverse views xz, steps of manufacturing a superposed transistor device, according to a first embodiment of the present invention.

FIGS. 1B, 2B, 3B, 4B, 5B, 6B, 7B, 8B, 9B, 10B, 11B, 12B, 13B, 14B, and 15B schematically illustrate along transverse views yz, the same steps of manufacturing the device, according to a first embodiment of the present invention.

FIGS. 16A and 16B schematically illustrate a manufacturing variant according to an embodiment of the present invention.

FIGS. 17A, 18A, 19A, 20A, 21A, 22A, 23A, 24A, and 25A schematically illustrate along transverse views xz, steps of manufacturing a superposed transistor device, according to a second embodiment of the present invention.

FIGS. 17B, 18B, 19B, 20B, 21B, 22B, 23B, 24B, and 25B schematically illustrate along transverse views yz, the same steps of manufacturing the device according to a second embodiment of the present invention.

FIGS. 22A and 22B illustrate, in particular, steps alternative to the step illustrated in FIGS. 21A, 21B.

In the figures in transverse views, cutting planes are indicated (A-A′, B-B′, . . . , P-P′) with references crossed with the cutting planes of the corresponding figures. The drawings are given as examples, and are not limiting of the invention. They constitute principle schematic representations intended to facilitate the understanding of the invention and are not necessarily to the scale of practical applications. In particular, in the principle diagrams, the thicknesses and/or the dimensions of the different layers, patterns and raised elements are not representative of reality. For reasons of clarity, all of the alphanumerical references are not systematically repeated from one figure to another. It is understood that the elements already described and referenced, when they are reproduced in another figure, typically have the same alphanumerical references, even if these are not explicitly mentioned. A person skilled in the art will identify, without difficulty, one same element reproduced in different figures.

### DETAILED DESCRIPTION

Before starting a detailed review of embodiments of the invention, optional features are stated below, which can optionally be used in association or alternatively:

According to an example, the secondary parts of the source contact and the secondary parts of the drain contact opposite, along the sequent direction x, are separated by dielectric plugs. The source and drain contacts are insulated from one another. The dielectric plugs further facilitate the formation of the secondary parts of the source and drain contacts.

According to an example, the dielectric plugs further separate two successive stacked channels, along the main direction z.

According to an example, the dielectric plugs have a dimension l₇₀, along the sequent direction x, less than a dimension l₅₀ of the gate-all-around at said successive stacked channels, such that the dielectric plugs define an effective gate length Lg shorter than the dimension l₅₀ of the gate-all-around, for the successive stacked channels. This makes it possible to physically define the effective gate length Lg of the channels.

According to an example, each source comprises at least one so-called horizontal portion in contact with a secondary part of the source contact, and each drain comprises at least one so-called horizontal portion in contact with a secondary part of the drain contact. This improves the quality of the electric contact between the source (drain) contacts and the sources (the drains).

According to an example, each source comprises a so-called vertical portion in contact with the main part of the source contact, and a so-called horizontal portion in contact with a secondary part of the source contact, and each drain comprises a so-called vertical portion in contact with the main part of the drain contact, and a so-called horizontal portion in contact with a secondary part of the drain contact. This improves the quality of the electric contact between the source (drain) contacts and the sources (the drains).

According to an example, each source only comprises one so-called horizontal portion in contact with a secondary part of the source contact, and in which each drain only comprises one so-called horizontal portion in contact with a secondary part of the drain contact. This avoids a delamination phenomenon of the source and drain contacts.

According to an example, the device comprises one single source common to all the channels and one single drain common to all the channels.

According to an example, the semiconductor material of the channels is taken from among:
the transition metal dichalcogenides MX2 with M taken from among molybdenum (Mo) or tungsten (W), and X taken from among sulphur (S), selenium (Se) or tellurium (Te), or
a semiconductor oxide, for example, IGZO (Indium Gallium Zinc Oxide), In₂O₃, IWO (Tungsten Doped Indium Oxide), ITO (Indium Tin Oxide), IAZO (Indium Aluminium Zinc Oxide), InGaZnO, InGaO, InZnO or an amorphous semiconductor oxide,
graphene, hexagonal boron nitride or phosphorene.

According to an example, the method comprises, after deposition of the semiconductor material-based layer, a partial removal of said layer on flanks of the second pattern, substantially parallel to the main direction z, in particular, on flanks of the first spacers and on flanks of the internal spacers, such that the source and drain contacts are directly in contact with the flanks of the first spacers and with the flanks of the internal spacers. This avoids a delamination phenomenon of the source and drain contacts.

According to an example, the partial etching of the dielectric plugs is configured, such that the dimension l₇₀ of the dielectric plugs is less than a dimension l₁₀ of the remaining parts of the first layers, or than a dimension l₅₀ of the gates-all-around, along the sequent direction x. This makes it possible to define a shorter effective gate length Lg for the channels.

According to an example, the formation of the gates-all-around is done before the deposition of the semiconductor material-based layer. This type of method, called “Gate-Last and Channel-Last”, where the functional gate is formed in replacing a sacrificial gate before the deposition of the semiconductor material-based layer, makes it possible to preserve the dimensional and structural features of the semiconductor material-based layer. The thermal budget linked to the formation of the functional gate does not impact the properties of the semiconductor material-based layer.

According to an example, the method comprises the steps sequenced below in the following order:
Providing, on a substrate S, a stack E along the main direction z comprising first layers made of a first material alternated with second layers made of a second material, the first and second materials being different from the semiconductor material of the channels of the device,
Forming, in this stack E, first openings defining first patterns,
Forming sacrificial gates mounted on the first patterns and partially in the first openings,
Forming first spacers on the first patterns and bordering the sacrificial gates,
Forming, in the first patterns, second openings defining second patterns,
Partially removing, from the second openings, the first material of the first layers selectively at the second material of the second layers, so as to form first spaces under the first spacers, and preferably partially under the sacrificial gates,
Filling the first spaces with a dielectric material to form internal spacers,
Filling the second openings with a masking layer,
Removing the sacrificial gates, so as to form third openings,
Totally removing, from the third openings, the first material of the remaining parts of the first layers, so as to form third spaces,
Forming a dielectric layer, called gate dielectric layer, in the third spaces,
Filling with a material, called gate material, the third spaces, so as to form the gates-all-around,
At least partially removing the masking layer, so as to form, again, the second openings,
Totally removing, from the second openings, the second material of the second layers, so as to form second spaces,
Depositing a layer with the basis of a semiconductor material on exposed surfaces of the second spaces, without totally filling the second spaces, said layer being intended to form the semiconductor material-based channels, and the semiconductor material-based sources and drains,
Filling the second spaces with a dielectric material, so as to form dielectric plugs occupying the second spaces,
Partially etching the dielectric plugs from the second openings, on either side of the second patterns, so as to reduce a dimension l₇₀ of said dielectric plugs along the sequent direction x, the second spaces being obstructed in their centres by the dielectric plugs,
Filling the second spaces and the second openings with at least one metal material, so as to form the source and drain contacts in the form of first and second combs opposite one another.

According to an example, the stack E comprises at least four first layers of the first material alternated with three second layers of the second material. This makes it possible to obtain a gate-all-around for all the stacked channels of the device.

According to an example, the stack comprises an alternance of a first layer with a second layer. Preferably, said first layer and said second layer are in contact. According to an example, the final device comprises transistor channels formed after selective removal of the second layers of the initial stack. According to an example, the final device comprises gates-all-around formed after selective removal of the first layers of the initial stack. The initial stack typically does not comprise, neither the semiconductor material of the transistor channels, nor the material of the gates-all-around.

According to an example, the internal spacers are silicon nitride-based. Before formation of the internal spacers, the partial removal of the first material of the first layers is configured to preserve parts of the first layers between the first spaces. These parts are called remaining parts. The remaining parts of the first layers are thus located between the first spaces. The internal spacers are preferably in contact with the remaining parts of the first layers, before formation of the gates-all-around.

According to an example, the formation of the first spaces is configured, such that the first spaces extend under the sacrificial gates. The width of the internal spacers is thus increased. This makes it possible to reduce the parasitic capacity due to the proximity of the source and drain contacts.

According to an example, the secondary parts of the source and drain contacts are made of a metal different from the main parts of the source and drain contacts. Such an engineering of materials in the source and drain contacts makes it possible, for example, to optimise the access resistance of the contacts. This also makes it possible to use a “non-planarisable” material at the fingers of the source and drain contacts. This increases the options to use materials of interest.

According to an option, the secondary parts made of a metal material different from the main parts can also locally introduce a stress state at the sources and drains. The transport properties of the sources and drains can be improved. The channels can also be mechanically stressed, through sources and drains. The transport at the channel can also be advantageously modified.

According to an example, after partial etching of the dielectric plugs and before filling the second spaces, a second semiconductor material, preferably a two-dimensional (2D) material, is deposited in the second spaces without totally filling the second spaces. This makes it possible to thicken the sources and drains of the device. This makes it possible to improve the electric contact with the source and drain contacts. This compensates for a possible damaging of the semiconductor material at the sources and drains of the device.

According to an example, the formation of the gates-all-around is done after the deposition of the semiconductor material-based layer. This type of method, called “Channel-First and Gate-Last”, where the functional gate is formed at the end of the method, by replacing a sacrificial gate, makes it possible to preserve the dimensional features of the gate. The thermal budget linked to the deposition of the semiconductor material does not impact the equivalent gate oxide thickness at the interface with the gate. The structural and electric features of the functional gate are better controlled.

According to an example, the deposition of the semiconductor material-based layer is done by chemical vapour deposition or by atomic layer deposition. Chemical vapour depositions are easy to implement. Atomic layer depositions make it possible to accurately control the thickness of the semiconductor material-based layer.

According to an example, the semiconductor material is chosen from among transition metal dichalcogenides MX2 with M taken from among molybdenum (Mo) or tungsten (W), and X taken from among sulphur (S), selenium (Se) or tellurium (Te).

According to another example, the semiconductor material is chosen with the basis of a semiconductor oxide, for example, IGZO—(Indium Gallium Zinc Oxide)-, In₂O₃-, IWO—(Tungsten Doped Indium Oxide)-, ITO—(Indium Tin Oxide)-, IAZO (Indium Aluminium Zinc Oxide)-, InGaZnO-, InGaO-, InZnO-based, or with the basis of an amorphous semiconductor oxide.

According to an example, the first material is chosen as SiGe and the second material is chosen as Si, or vice versa. These materials can be easily epitaxially grown by conventional technological microelectronics methods. This makes it possible to benefit from current technological pathways. The cost of the method is reduced.

According to an example, the formation of the sacrificial gates is done, such that the sacrificial gates extend over the entire height of the first openings. According to an example, the first openings extend along the entire height of the stack of the first and second layers. The sacrificial gates extend over the entire height of the stack. The sacrificial gates typically bear on the substrate. This makes it possible to give an access to all the layers of the stack via the third openings.

According to an example, the substrate is a silicon-based solid substrate.

According to an example, the stack comprises as many first layers of the first material, as second layers of the second material.

According to an example, the removal of the first material of the first layers selectively at the second material of the second layers is done by a first selective etching having a selectivity S_{10:20} of at least 5:1, preferably at least 10:1. This first selective etching is typically stopped at the time.

According to an example, the removal of the second material of the second layers selectively at the first material of the first layers is done by a second selective etching having a selectivity S_{20:10} of at least 5:1, preferably at least 10:1.

Unless incompatible, it is understood that all of the optional features above can be combined, so as to form an embodiment, which is not necessarily illustrated or described. Such an embodiment is clearly not excluded from the invention. The features and the advantages of an aspect of the invention, for example, the device or the method, can be adapted mutatis mutandis to the other aspect of the invention.

The invention generally relates to a microelectronic device with GAA transistors and a method for manufacturing such a device. This microelectronic device can have a “GAA stacked nanosheet”-type architecture. A GAA stacked nanowire-type architecture is also possible.

Nanowires or nanosheets typically each comprise a conduction channel of a transistor. These channels are stacked along a direction z. This means that they each occupy a given altitude level along the direction z. A level can be defined between two planes perpendicular to the direction z.

Advantageously, the method according to the invention can be implemented for the production of MOS GAA transistors for 2 nm and sub-2 nm technological nodes.

A microelectronic device comprising superposed GAA transistors can be advantageously integrated in logic systems having 3D architectures. These transistors can, in particular, be associated with other structural or functional elements, so as to design complex systems.

A particular aspect of the invention relates to the implementation of 2D materials to produce nanowires or nanosheets of the device.

The 2D materials typically correspond to compounds having a lamellar structure constituted of two-dimensional sheetlets, stacked along the crystallographic axis c. The atomic bonds within each sheetlet are strong, of a covalent nature. The bonds between sheetlets are a lot weaker, of the Van der Waals type. These two-dimensional sheetlets are also called monolayers.

In the scope of the present invention, the monolayers are preferably semiconductor monolayers of the MX2 type, where M is molybdenum (Mo) or tungsten (W), and X is sulphur (S) or selenium (Se). Each “monolayer” is, in this case, composed of a metal cation plane M inserted between two anion planes X. A monolayer therefore comprises, in this case, typically three atomic planes: the atoms of the transition metal (Mo or W) form a plane sandwiched between two chalcogen planes (S, Se or Te, for example). Each transition metal atom is connected to six chalcogen atoms. These anions are in prismatic trigonal coordination with respect to the metal atoms. The transition metal dichalcogenide MX2 monolayers have a hexagonal atomic lattice.

The transition metal dichalcogenide MX2 monolayers are preferably MoS₂, MoSe₂, MoTe₂, WS₂, WSe₂ molybdenum disulphide-based.

An alternative option relates to the implementation of semiconductor oxides to produce the nanowires or nanosheets of the device. These semiconductor oxides are preferably IGZO—(Indium Gallium Zinc Oxide)-, In₂O₃-, IWO—(Tungsten Doped Indium Oxide)-, InGaZnO-, InGaO-, InZnO-, IAZO- or ITO—(Indium Tin Oxide)-based. Another option relates to the implementation of graphene, hexagonal boron nitride “h-BN”, phosphorene (also called “Black Phosphorous” BP), in particular, in the form of a monolayer.

It is specified that, in the scope of the present invention, the terms “on”, “surmounts”, “covers”, “underlying”, “opposite” and their equivalents do not necessarily mean “in contact with”. Thus, for example, the deposition or the application of a first layer on a second layer, does not compulsorily mean that the two layers are directly in contact with one another, but means that the first layer covers, at least partially, the second layer by being either directly in contact with it, or by being separated from it by at least one other layer or at least one other element.

By a substrate, a film, a layer “with the basis” of a material A, this means a substrate, a film, a layer comprising this material A only, or this material A, and optionally other materials, for example, doping elements or alloy elements. Thus, a silicon nitride SIN-based spacer can, for example, comprise non-stoichiometric silicon nitride (SiN), or stoichiometric silicon nitride (Si₃N₄), or also, a silicon oxy-nitride (SiON).

By a “continuous” layer, this means a layer having a continuity of material. Typically, a continuous layer can coat the second layers of the second patterns, or cover the second spaces of the second patterns.

The word “dielectric” qualifies a material, the electrical conductivity of which is sufficiently low in the given application to serve as an insulator. In the present invention, a dielectric material preferably has a dielectric constant less than 20, and preferably, a dielectric constant less than 7.

Several embodiments of the invention implementing successive steps of the manufacturing method are described below. Unless explicitly mentioned, the adjective “successive” does not necessarily imply, even if this is generally preferred, that the steps immediately follow one another, intermediate steps being able to separate them.

Moreover, the term “step” means the carrying out of a part of the method, and can mean a set of substeps.

Moreover, the term “step” does not compulsorily mean that the actions carried out during a step are simultaneous or immediately successive. Certain actions of a first step can, in particular, be followed by actions linked to a different step, and other actions of the first step can then be resumed. Thus, the term “step” does not necessarily mean single and inseparable actions over time and in the sequence of the phases of the method.

By “selective etching with respect to” or “etching having a selectivity with respect to” means an etching configured to remove a material A or a layer 4 with respect to a material B or a layer B, and having an etching speed of the material A greater than the etching speed of the material B. The selectivity is the ratio between the etching speed of the material A to the etching speed of the material B. It is referenced S_{A:B}. A selectivity S_{A:B} of 10:1 means that the etching speed of the material A is ten times greater than the etching speed of the material B.

The different patterns formed during the manufacturing steps typically have a structure intended to develop during the steps of the method. Thus, the patterns can comprise the sacrificial layers of the initial stack, the 2D material- or semiconductor oxide-based layers, the dielectric layers, continuous or discontinuous.

A preferably orthonormal system, comprising the axes x, y, z is represented in the accompanying figures.

In the present patent application, thickness will preferably be referred to for a layer or a film, and height will preferably be referred to for a device or a structure. The thickness is taken along a direction normal to the main extension plane of the layer or of the film. Thus, a superficial silicon (topSi) layer typically has a thickness along z. A gate pattern formed on such a superficial layer has a height along z. The relative terms “on”, “surmounts”, “under”, “underlying” refer to positions taken along the direction z. A “lateral” dimension corresponds to a dimension along a direction of the plane xy. By a “lateral” extension or “laterally”, this means an extension along one or more directions of the plane xy.

An element located “in vertical alignment with” or “to the right of” another element means that these two elements are both located on one same line perpendicular to a plane in which a lower or upper face of a substrate mainly extends, i.e. on one same line oriented vertically in the figures in a transverse view.

The terms “substantially”, “around”, “about” mean plus or minus 10%, and preferably, plus or minus 5%. Moreover, the terms “between . . . and . . . ” and equivalent mean that the limits are inclusive, unless otherwise mentioned.

The description below has examples of implementing the method according to the invention in a context of developing a complex 3D device. The scope of this description is clearly not limiting of the invention.

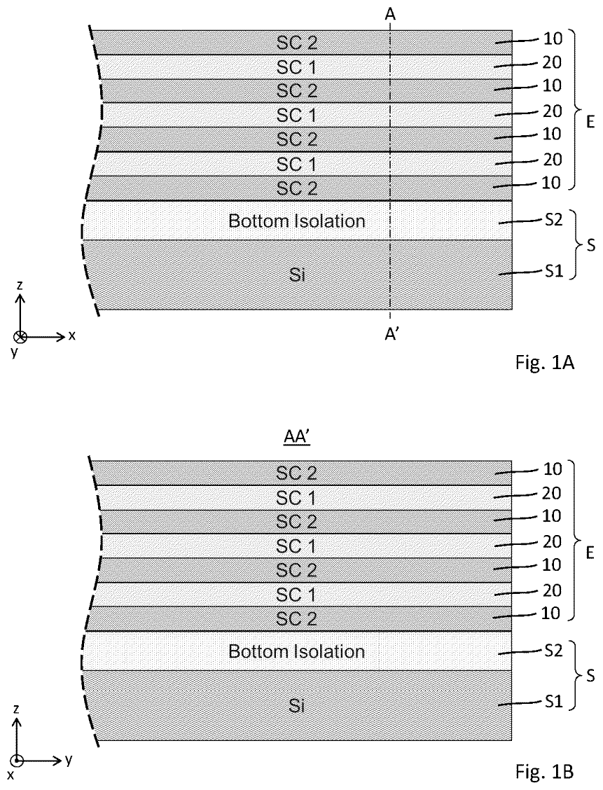

FIGS. 1A, 1B to 15A, 15B schematically illustrate steps of manufacturing a device comprising stacked GAA transistors, according to a so-called “Gate-Last and Channel-Last” embodiment. Figures nA (n=1 . . . 15) correspond to transverse views along xz each illustrating a different step of the manufacturing method. Figures nB (n=1 . . . 15) correspond to transverse views along yz each illustrating the same step as the corresponding figure nA.

As illustrated in FIGS. 1A, 1B, a first step consists of producing a stack E of layers 10, 20 on a substrate S. The substrate S can be an SOI—(Silicon On Insulator)-, GeOI—(Germanium On Insulator)- or SGOI—(Silicon-Germanium On Insulator)-type substrate. These known substrates comprise, according to common terminology for a person skilled in the art, a so-called “bulk Si” thick silicon layer S1, a so-called “BOX” (Buried Oxide) silicon oxide layer S2, and a superficial thin layer, respectively silicon-, germanium- or silicon-germanium-based. This superficial thin layer can advantageously correspond to the first layer 10 of the stack E.

Alternatively, the substrate S can be a “bulk Si” solid substrate.

The stack E comprises, according to an example, an alternance of silicon-germanium (SiGe) first layers 10 and of silicon (Si) second layers 20.

The concentration of Ge in the SiGe alloy can be 20%, 30% or 45%, for example. This concentration of germanium is chosen, so as to enable a good selectivity of the etching of SiGe with respect to Si, during selective etching steps. The greater the concentration of Ge, the greater the selectivity of Si during the subsequent removal of SiGe. This stack E is advantageously formed by epitaxy of the SiGe 10 and Si 20 layers. This step of forming the stack E is inexpensive and well-known to a person skilled in the art. The thicknesses of the Si and SiGe layers can be typically around 10 nm, and more generally, between 5 nm and 20 nm, for example. In a known manner, in order to avoid the formation of structural defects, the maximum thicknesses permitted for the SiGe layers 10 depend, in particular, on the chosen concentration of Ge.

In the example illustrated in FIGS. 1A, 1B, four Si layers 10 are alternated with three epitaxially grown SiGe layers 20. An Si/SiGe superlattice is thus obtained. The number of Si and SiGe layers can naturally be increased. This ultimately makes it possible to increase the number of transistors stacked in the final device.

Generally, the first material of the first layers 10 and the second material of the second layers 20 are chosen, such that one can be etched selectively with respect to the other. Thus, other pairs of first and second materials are possible. By respecting this selectivity to etching condition, the first and second materials can be chosen from among dielectric materials (oxides and nitrides, for example), semiconductor materials, metal materials. According to an example, the first material of the first layers 10 is an oxide-based dielectric, and the second material of the second layers 20 is amorphous silicon. In this case, the dielectric material of the internal spacers subsequently formed is typically nitride-based. There are other possible combinations.

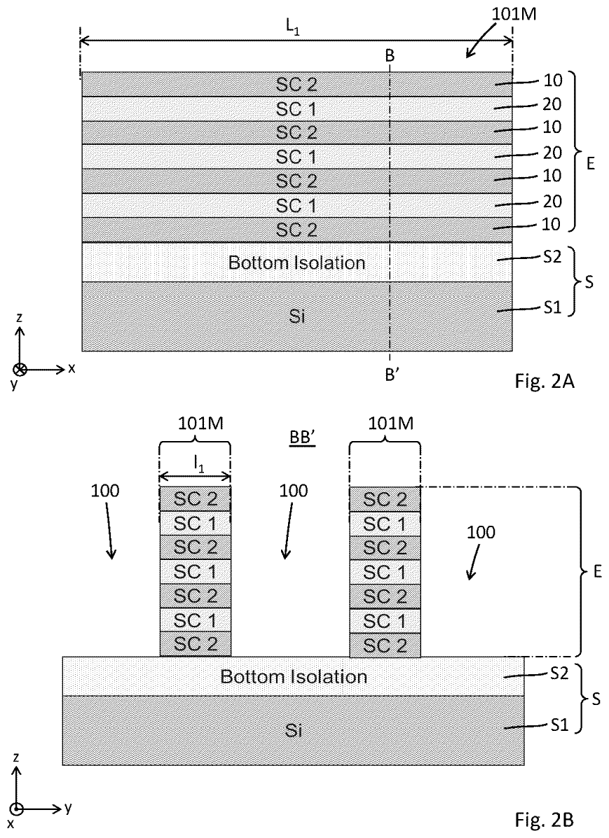

As illustrated in FIGS. 2A, 2B, a conventional lithography/etching step is carried out, in order to define first patterns 101M, and first openings 100. The etching is anisotropic and directed along z. It is configured to etch the stack E, in this case, the Si/SiGe superlattice, over its entire height, by stopping on the substrate S, in this case, the S₂ BOX. It can be achieved by plasma, by using an HBr/O₂ etching chemistry. The first patterns 101M can have a length L₁ along x of between 100 nm and 500 nm. They preferably have a width I₁ along y of between 10 nm and 120 nm, for example, around 40 nm. This first structuration of the stack E in the form of fins, makes it possible to define a plurality of superposed nanowires or nanosheets.

For clarity, the following figures iB (i=3 . . . 15) only illustrate one single “fin” pattern 101M.

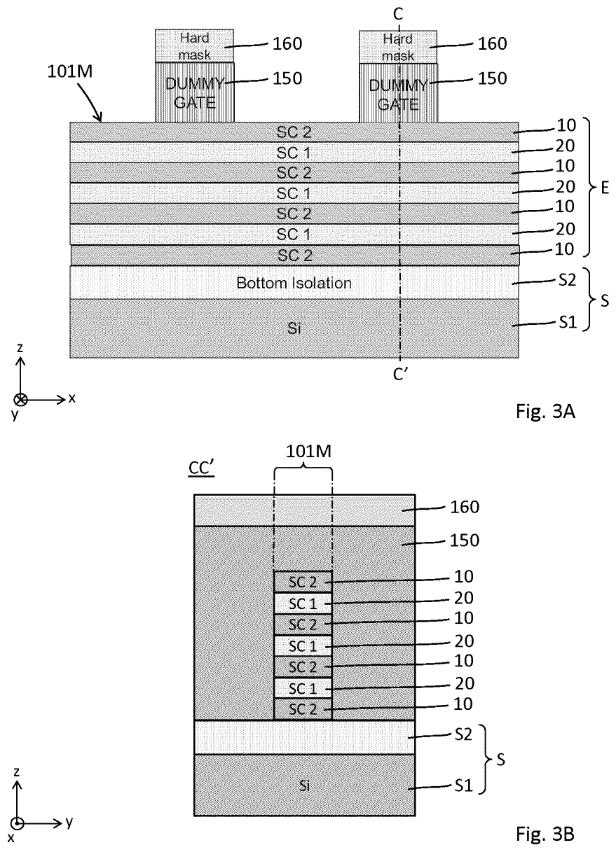

As illustrated in FIGS. 3A, 3B, sacrificial gates 150 are then formed on the “fin” patterns 101M. The formation of these sacrificial gates 150 is done typically by lithography/etching. The formation of the sacrificial gates 150 is configured, such that the sacrificial gates 150 are mounted on the “fin” patterns 101M, as illustrated in FIG. 3B. The sacrificial gates 150 typically comprise an upper part located on the “fin” pattern 101M, and lateral parts located on the lateral flanks of the “fin” pattern 101M. The sacrificial gates 150 typically bear on the substrate S. At this stage, the sacrificial gates 150 are typically surmounted by an etching mask 160, called hard mask, implemented in the structuration of the sacrificial gates 150. The sacrificial gates 150 are, for example, polycrystalline silicon- or amorphous silicon-based, or also polycrystalline SiGe- or amorphous SiGe-based.

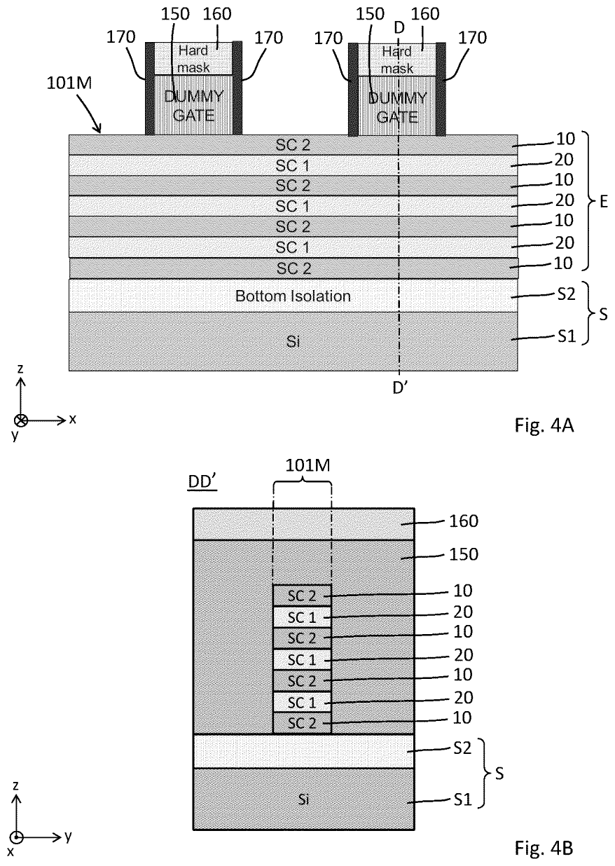

As illustrated in FIGS. 4A, 4B, first spacers 170 are then formed on the flanks oriented along yz of the sacrificial gates 150. Generally, projecting along z, these spacers form a continuous ring around each sacrificial gate 150, with a closed contour. In a transverse view, however, along the plane xz illustrated in FIG. 4A, the first spacer 170 has two parts opposite one another on each of the flanks of the sacrificial gate 150. These two parts are generally referred to as being the first spacers 170, even if these can be considered as belonging to one single and same spacer. The first spacers 170 extend typically up to an upper face of the hard masks 160. The first spacers 170 are typically silicon nitride SiN-based (dielectric constant k~7.5) or of a dielectric material with a low dielectric constant, for example, SiOCN (k~5.2), SiBCN (k~5.5), SiOC, SiCN, SlCO (k~4.5), SiO₂ (k~3.9).

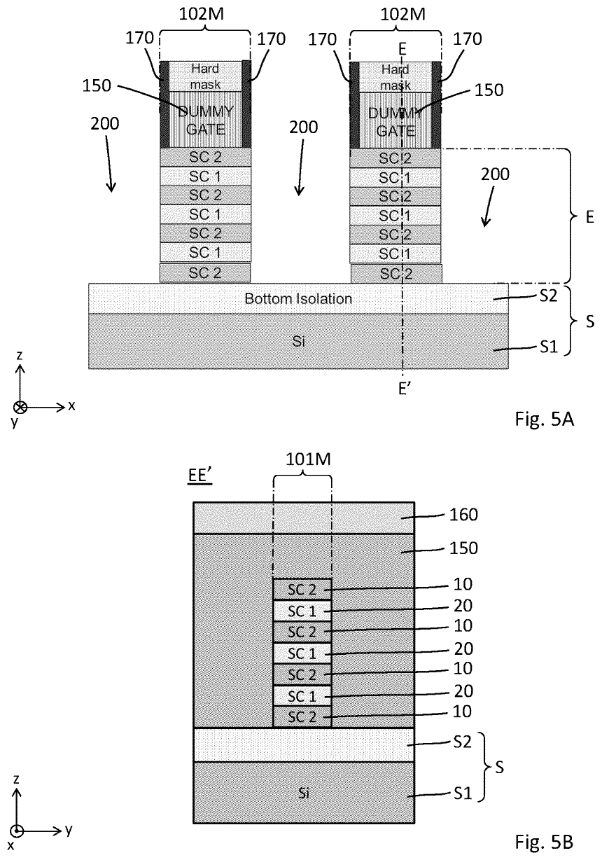

As illustrated in FIGS. 5A, 5B, after formation of the first spacers 170 by lithography/etching, the anisotropic etching along z is extended, in order to define second patterns 102M, and second openings 200. The etching is configured to etch the stack E over its entire height, by stopping on the substrate S. It can be achieved by plasma, by using an HBr/O₂ etching chemistry.

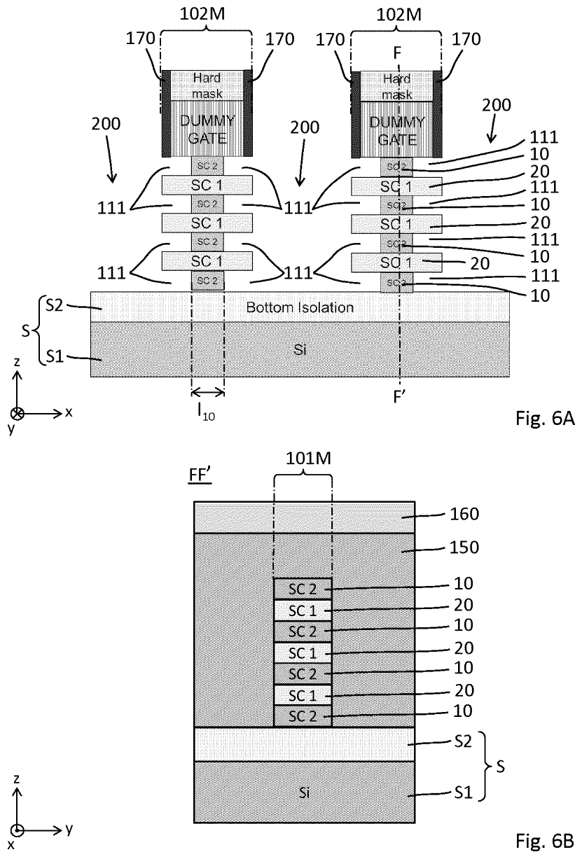

As illustrated in FIGS. 6A, 6B, after formation of the second openings 200, the first layers 10 partially etched selectively at the second layers 20, at the substrate S, at the sacrificial gates 150 and at the first spacers 170. The etching of the first material of the first layers 10 typically has a selectivity S_{10:20} with respect to the second material of the second layers 20, of at least 5:1, preferably at least 10:1. This partial etching aims to form first spaces 111 under the first spacers 170, and preferably under the sacrificial gates 150. This partial etching is typically stopped at the time. The partial etching has an isotropic character, and can be achieved wet or dry, from the second openings 200. From this partial etching, central parts of the first layers 10 are preserved under the sacrificial gates 150. These central parts typically have a dimension l₁₀ less than the dimension along x of the sacrificial gates 150 (also called “dummy gates”). This makes it possible to reduce the parasitic capacities via increasing the thickness of the internal spacers (which can penetrate under the metal gate).

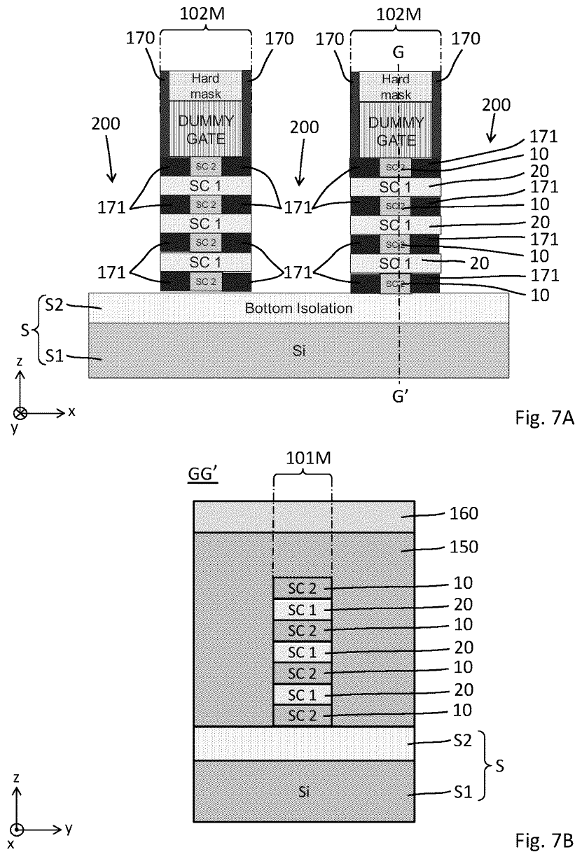

As illustrated in FIGS. 7A, 7B, the first spaces 111 are then filled with a dielectric material to form internal spacers 171. These “internal” spacers 171 are integrated in the stack E. They are in contact with the central parts of the first layers 10. The formation of the internal spacers 171 is done typically from the second openings 200. As above, the internal spacers 171 can be silicon nitride SIN-based (dielectric constant k~7.5) or of a dielectric material with a low dielectric constant, for example, SiOCN (k~5.2), SiBCN (k~5.5), SiOC, SiCN, SlCO (k~4.5), SiO₂ (k~3.9). The material of these internal spacers 171 can be different from that of the first spacers 170. The internal spacers 171 typically have a dimension along x greater than or equal to 3nm, preferably greater than or equal to 5 nm. As the dimension l₁₀ of the central parts of the first layers 10 is less than the dimension along x of the sacrificial gates 150, the internal spacers 171 extend under the sacrificial gates 150, the internal spacers 171 extend under the sacrificial gates 150 (subsequently replaced by metal functional gates). This makes it possible to reduce the parasitic capacities in the device.

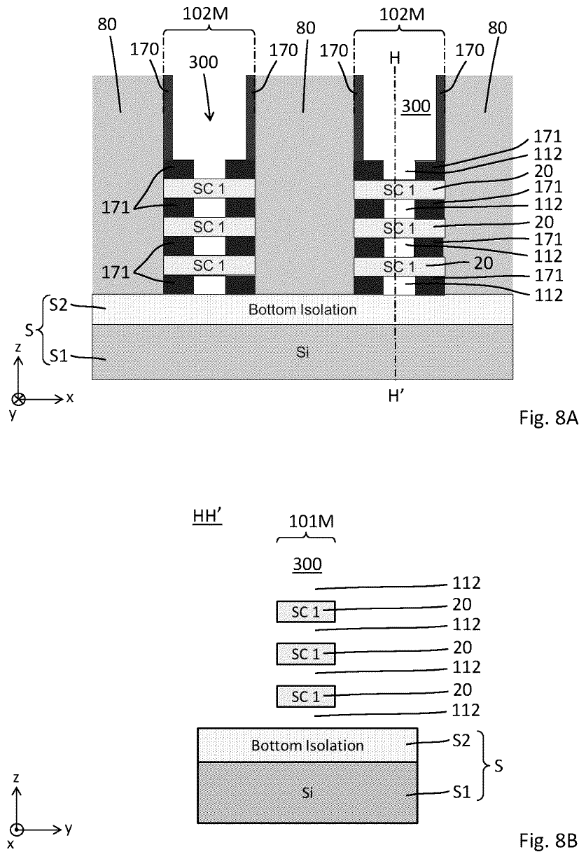

As illustrated in FIGS. 8A, 8B, the second openings 200 are first filled with a masking layer 80. This layer 80 makes it possible, in particular, to better mechanically hold the second layers 20. The hard masks 160 and the sacrificial gates 150 are then removed to form the third openings 300. The first material of the remaining parts of the first layers 10 is then totally removed from the third openings 300, by selective etching opposite the second layers 20. This makes it possible to form the third spaces 112. The third spaces 112 and the third openings 300 surround the exposed central parts of the second layers 20, as illustrated in FIG. 8B.

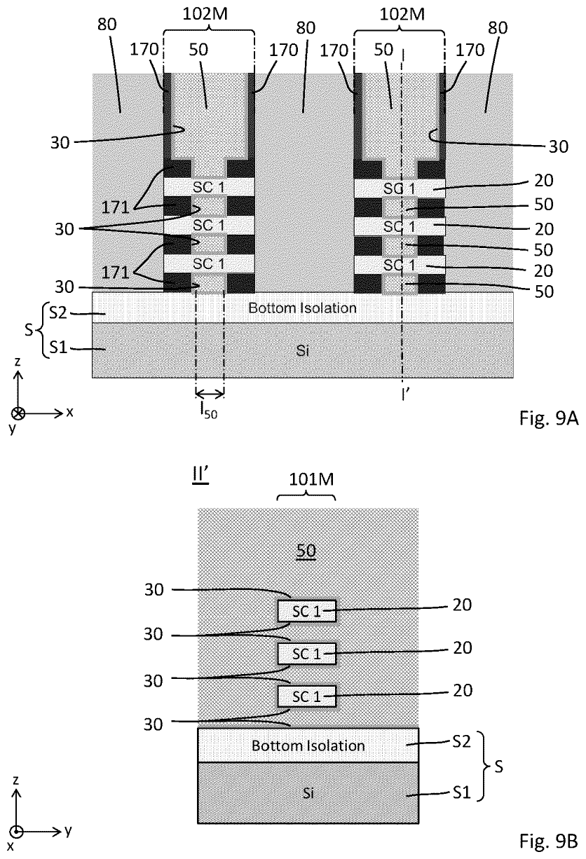

As illustrated in FIGS. 9A, 9B, a gate dielectric layer 30 is deposited in the third openings 300 and in the third spaces 112, so as to form a continuous layer covering the third openings 300 and the third spaces 112. This dielectric layer 30 is typically with the basis of a high permittivity material, for example, HfO₂-, HfSiO₄-, La₂O₃-, LaAlO₃-, ZrO₂-, ZrSiO₄-, Ta₂O₅-, TiO₂-, SrTiO₃-, Al₂O₃-based. It is intended to form the gate dielectric layer between the GAA transistor channels and their gates-all-around. It can be formed by chemical vapour deposition CVD, by low pressure chemical vapour deposition LPCVD, by atmospheric pressure chemical vapour deposition APCVD, by plasma enhanced chemical vapour deposition PECVD, or by atomic layer deposition ALD. The dielectric layer 30 typically has a thickness of between 1 nm and 5 nm.

The third openings 300 and the third spaces 112 are then filled with one or more metal layers, for example, W-, Al-, Ni-, Ti-, TiN-, TaN-, TiC-, TaC-, Ru-based, in order to form the gates-all-around 50 of the GAA transistors. These metal layers can be formed by CVD, LPCVD, APCVD, PECVD or ALD. A chemical-mechanical polishing CMP is typically done, in order to remove the excess material deposited on the patterns 102M. Stopping the CMP is done typically on the masking layer 80.

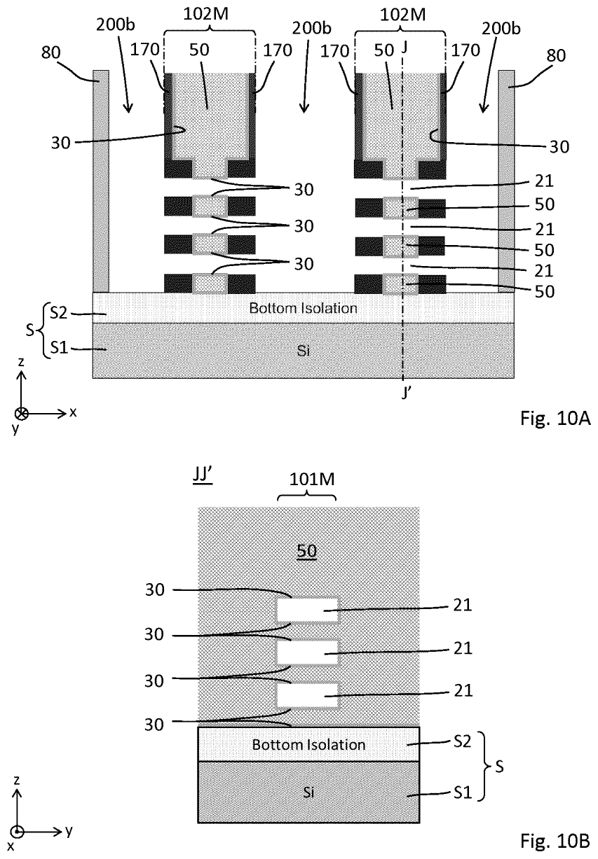

As illustrated in FIGS. 10A, 10B, the masking layer 80 is then partially removed to reform the second openings 200b. The second material of the second layers 20 is then totally removed, by selective etching from the second openings 200b, to form the second spaces 21. This total etching can be stopped at the time, possibly after an overetching time aiming to guarantee the total removal of the second material of the second layers 20. This total etching has an isotropic character, and can be done wet or dry. During the total etching of the second layers 20, the exposed surfaces of the gates-all-around 50 can be protected by a nitride-based protective plug, for example, to avoid a damaging linked to the total etching of the second layers 20.

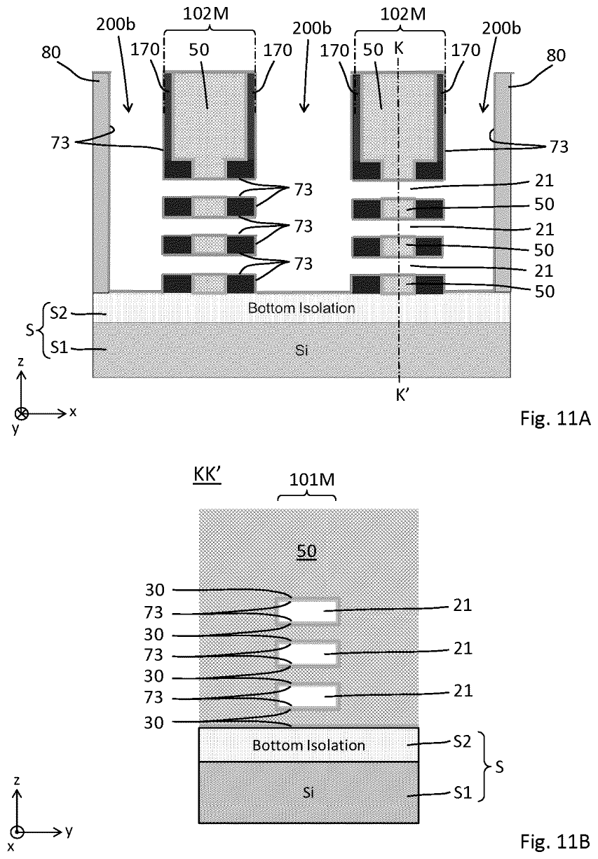

As illustrated in FIGS. 11A, 11B, optionally only, a dielectric layer 73 can be deposited in the second spaces 21. This dielectric layer 73 is typically with the basis of a high permittivity material, for example, HfO₂-based. It makes it possible to thicken the gate dielectric barrier formed by the dielectric layer 30, or to compensate for a possible consumption of the dielectric layer 30 during the total etching of the second layers 20. The dielectric layer 73 can be deposited as above, by CVD, LPCVD, APCVD, PECVD or ALD.

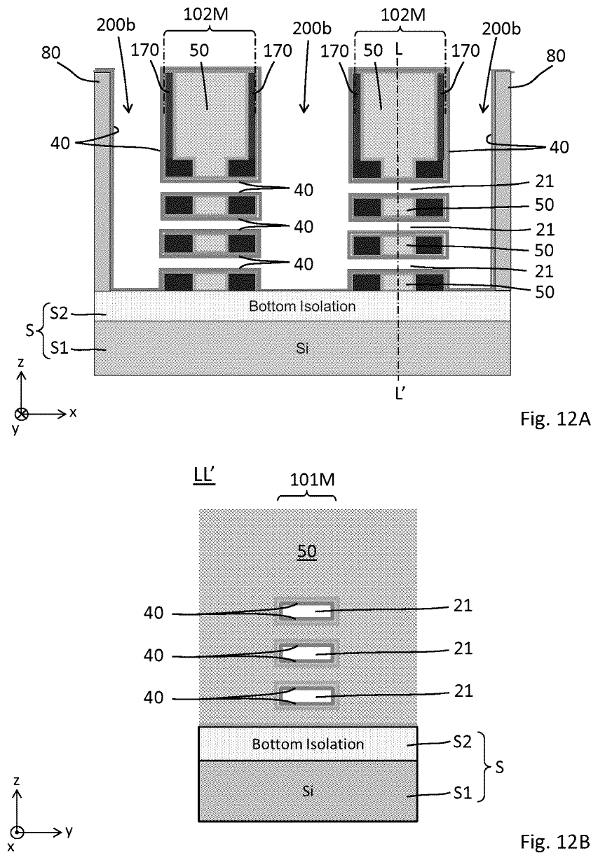

As illustrated in FIGS. 12A, 12B, a layer 40 with the basis of a semiconductor material is then deposited on the dielectric layer 73, or directly on the gate dielectric layer 30 in the second spaces 21. The layer 40 is also typically deposited outside of the second spaces 21, on the flanks of the first spacers 170 and of the internal spacers 171. The deposition of the layer 40 is configured, such that said layer 40 does not totally fill the second spaces 21. The thickness of the layer 40 located in the second spaces 21 can be significantly thinner than the thickness of the second initial layers. The layer 40 can have a thickness corresponding to a few atomic layers only, for example, between 1 and 5 atomic layers of semiconductor material.

This layer 40 is intended to form the GAA transistor channels substantially in vertical alignment with gates-all-around 50, and the sources and drains of these transistors substantially in vertical alignment with the internal spacers 171.

The semiconductor material of the layer 40 is advantageously a two-dimensional material taken from among the transition metal dichalcogenides MX2 with M, molybdenum (Mo) or tungsten (W), and X, sulphur (S), selenium (Se) or tellurium (Te). Such a 2D material can be advantageously deposited in the form of a thin layer comprising 1 to 5 atomic layers. The deposition of this 2D material can be done by CVD, MOCVD or ALD. According to another option, the semiconductor material of the layer 40 is a semiconductor oxide, such as ITO (Indium Tin Oxide), IGZO (Indium Gallium Zinc Oxide), IWO (Tungsten Doped Indium Oxide), indium oxide In₂O₃.

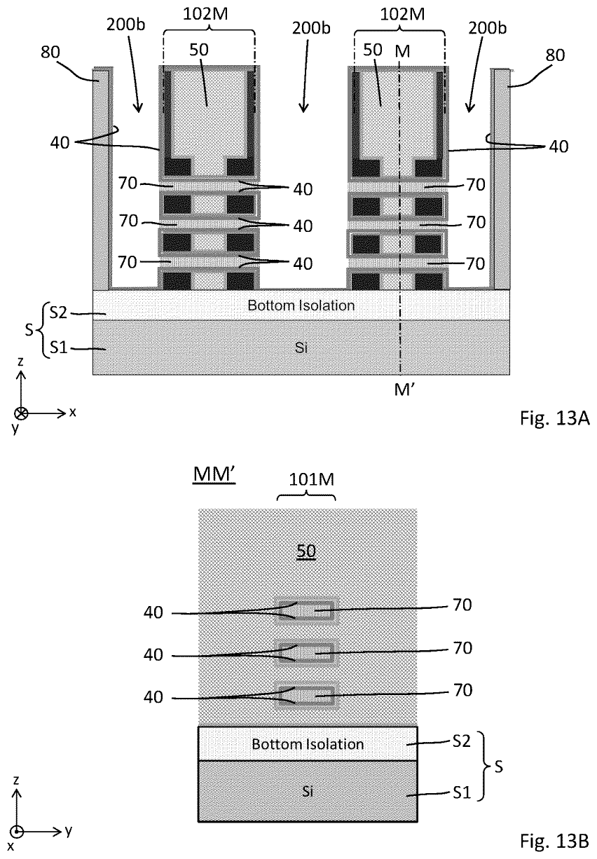

As illustrated in FIGS. 13A, 13B, a dielectric plug 70 is then formed between the horizontal portions of the layer 40, in the second spaces 21. This dielectric plug 70 can be formed by CVD or ALD or PEALD (Plasma Enhanced Atomic Layer Deposition), followed by an etching, conventionally.

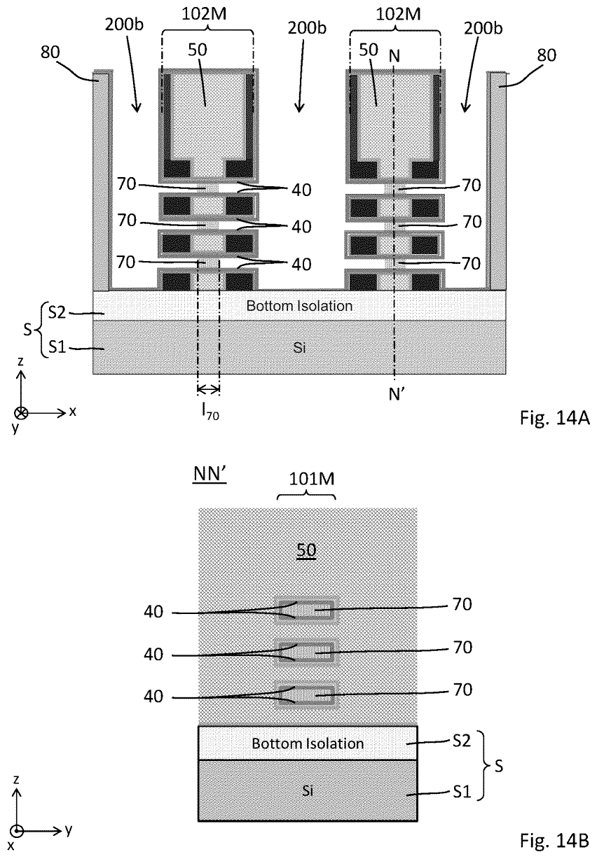

As illustrated in FIGS. 14A, 14B, the isotropic etching of the dielectric plug 70 is typically extended, so as to reduce the dimension l₇₀ along x of the dielectric plug 70. This etching is typically stopped at the time. The etching is done from the two sides of the pattern 102M, such that the “reduced” dielectric plug 70 is located substantially in the middle of the second spaces 21, along x. The dimension l₇₀ along x of the dielectric plug 70 is typically less than 10 nm, preferably less than 5 nm. Advantageously, the dimension l₇₀ along x of the dielectric plug 70 effectively defines the length of the GAA transistor channels. The etching of the dielectric plug 70 is typically extended, such that the dimension l₇₀ is less than the dimension l₅₀ of the gate-all-around 50. The action of extending the etching under the gates-all-around 50 facilitates controlling stopping the etchings at the time. The dimensional control along x of the dielectric plug 70 is improved. The dimensional control over the effective gate length of the GAA channels is thus advantageously improved.

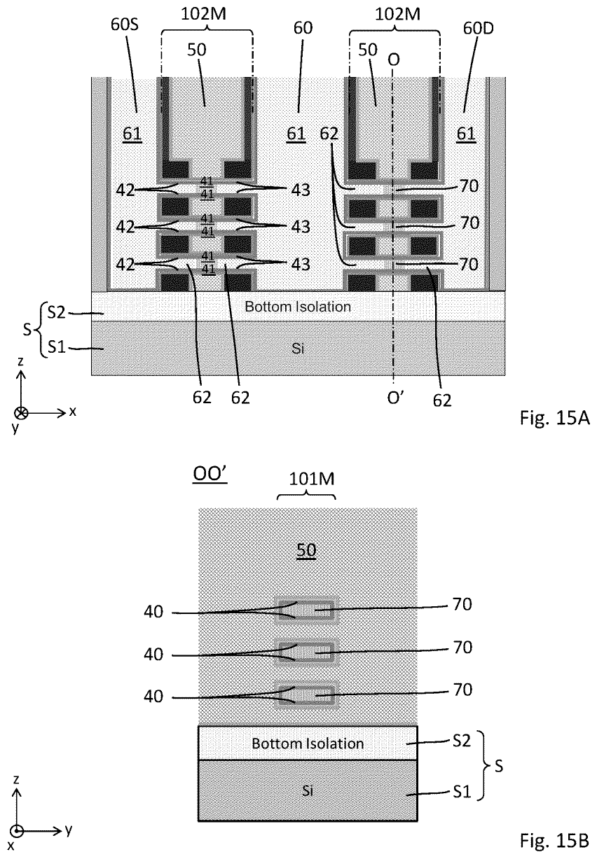

As illustrated in FIGS. 15A, 15B, the second openings 200b can then be filled with one or more metal layers, for example, Ti-, TiN-, W-based, in order to form the source and drain contacts 60S, 60, 60D. A chemical-mechanical polishing CMP is typically done in order to remove the excess metal deposited on the pattern 102M. Advantageously, the second spaces left vacant from reducing the dimension of the dielectric plug 70 are filled during the formation of the source and drain contacts 60S, 60, 60D. The source and drain contacts 60S, 60, 60D thus have fingers 62 extending under the internal spacers 171. These fingers 62 are directly in contact with the sources 42 and drains 43 with the basis of the material of the layer 40, along z. This improves the electric contact with the sources 42 and the drains 43. The source and drain contacts 60S, 60, 60D are thus presented in the form of combs opposite one another, on either side of the dielectric plugs 70. According to an option not illustrated, the fingers 62 are with the basis of a material different from the main part 61 of the contact 60S, 60, 60D. The main part 61 is, for example, TiN- and W-based, or NbN-based, and the fingers are, for example, Nb-based. This makes it possible to optimise the resistance of access of the source and drain contacts 60S, 60, 60D. This also makes it possible to use a “non-planarisable” material at the fingers 62, and a planarisable material of the main part 61.

A microelectronic device comprising six transistors stacked along x, with a gate-all-around 50, is thus advantageously obtained. The channels 41, the sources 42 and the drains 43 are preferably with the basis of a two-dimensional material. Source and drain contacts 60S, 60, 60D in the form of combs are electrically connected to these GAA transistors stacked along z.

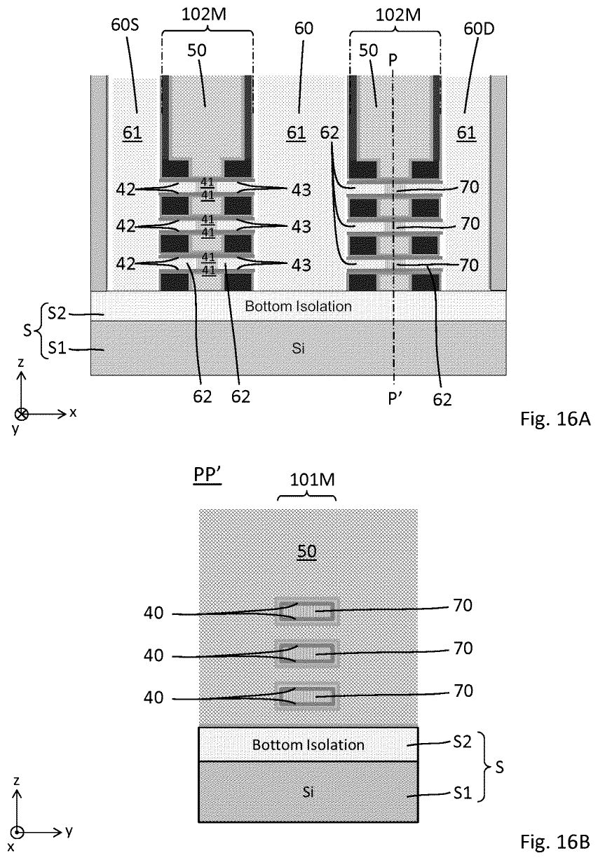

FIGS. 16A, 16B illustrate a variant of an embodiment in which the layer 40 is anisotropically etched along zn, before formation of the contacts 60S, 60, 60D, so as to only preserve the horizontal portions of the layer 40, in the second spaces 21. The vertical portions of the layer 40 are thus removed. This makes it possible to avoid a “side” contact between the main parts 61 of the contacts 60S, 60, 60D and the horizontal portions of the layer 40. The mechanical strength of the contacts 60S, 60, 60D is improved. In particular, the removal of the vertical portions of the layer 40 on the flanks of the spacers 170, 171 limits or removes a delaminating phenomenon of the contacts 60S, 60, 60D, in particular, during the planarisation of these contacts 60S, 60, 60D. The contact with the sources 42 and drains 43 is done, in this case, only or mainly via the fingers 62 of the contacts 60S, 60, 60D.

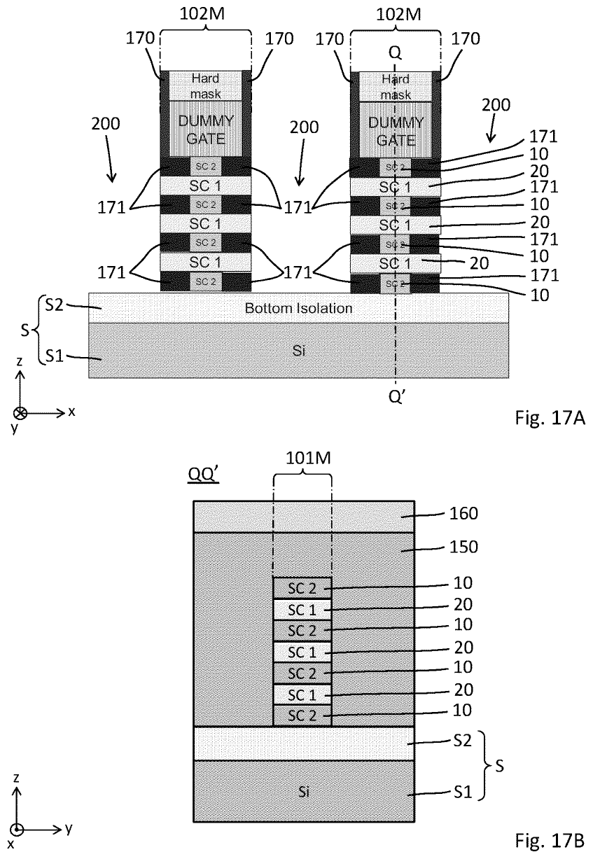

FIGS. 17A, 17B to 25A, 25B schematically illustrate steps of manufacturing a device comprising GAA transistors according to a so-called “Channel-First and Gate-Last” embodiment. Figures nA (n=17 . . . 25) correspond to transverse views along xz each illustrating a different manufacturing step. Figures nB (n=17 . . . 25) correspond to transverse views along yz each illustrating the same step as corresponding figure nA.

Only the different features of this second embodiment regarding the first embodiment are described below. The other features are considered identical to those of the first embodiment, in reference to the above.

FIGS. 17A, 17B illustrate the structures obtained from the formation of the internal spacers 171, similarly to what has been described above, in reference to FIGS. 1A, 1B to 7A, 7B.

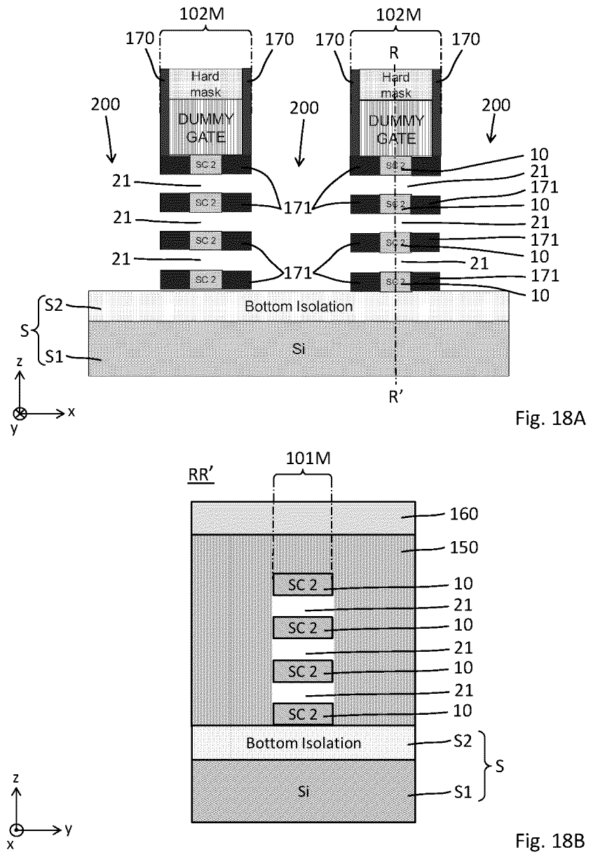

As illustrated in FIGS. 18A, 18B, the second layers 20 are totally etched selectively at the first layers 10, at the substrate S, and at the internal spacers 171. The etching of the second material of the second layers 20 typically has a selectivity S_{20:10} with respect to the first material of the first layers 10, of at least 5:1, preferably at least 10:1. This total etching aims to form the second spaces 21. The total etching typically has an isotropic character and can be done wet or dry, from the second openings 200.

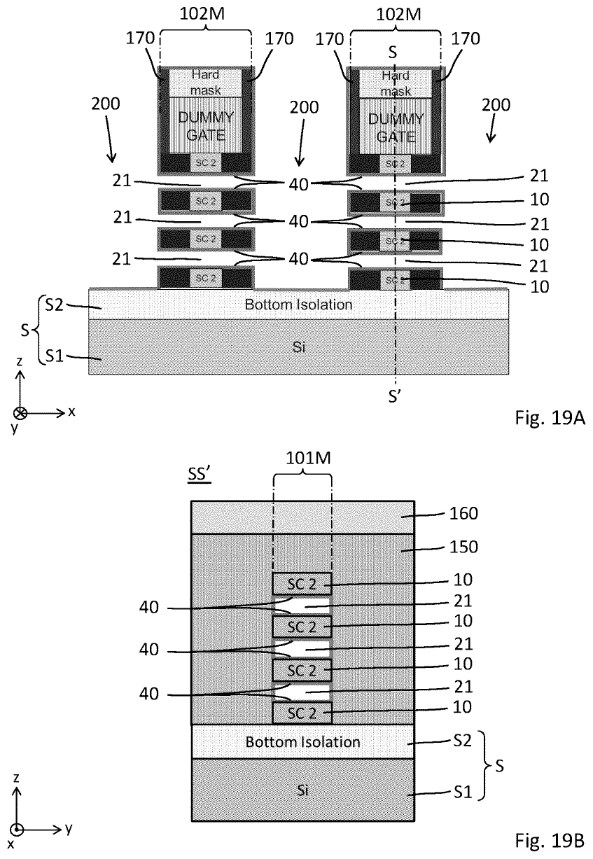

As illustrated in FIGS. 19A, 19B, after formation of the second spaces 21, the layer 40 with the basis of a semiconductor material is deposited on the remaining parts of the first layers 10 and on the internal spacers 171, in the second spaces 21. The layer 40 is deposited as above, and has the same features. Optionally, a so-called “inserted” dielectric layer can be deposited prior to the deposition of the layer 40. This makes it possible to subsequently protect the layer 40 during the removal of the remaining parts of the first layers 10.

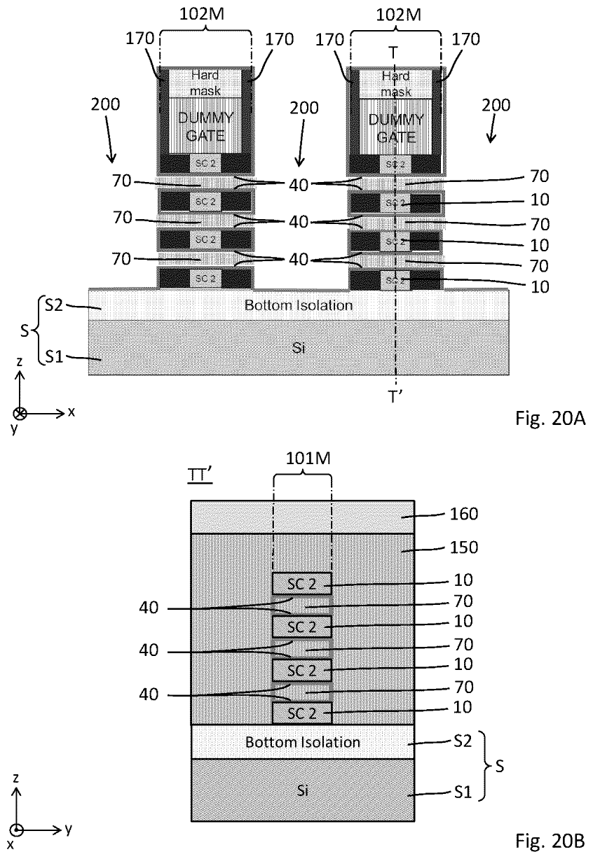

As illustrated in FIGS. 20A, 20B, the dielectric plug 70 is then formed between the horizontal portions of the layer 40, in the second spaces 21, as above.

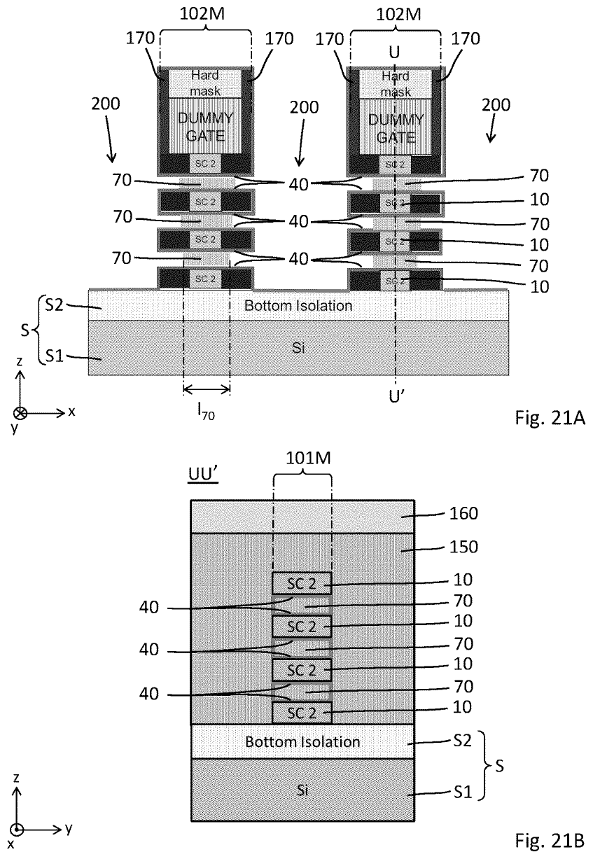

As illustrated in FIGS. 21A, 21B, the isotropic etching of the dielectric plug 70 is extended so as to reduce the dimension l₇₀ along x of the dielectric plug 70, as above. In the example illustrated in FIGS. 21A, 21B, the dimension l₇₀ along x of the dielectric plug 70 is greater than the dimension l₁₀ along x of the remaining parts of the first layers 10. The edges of the dielectric plug 70 are, in this case, located under the internal spacers 171.

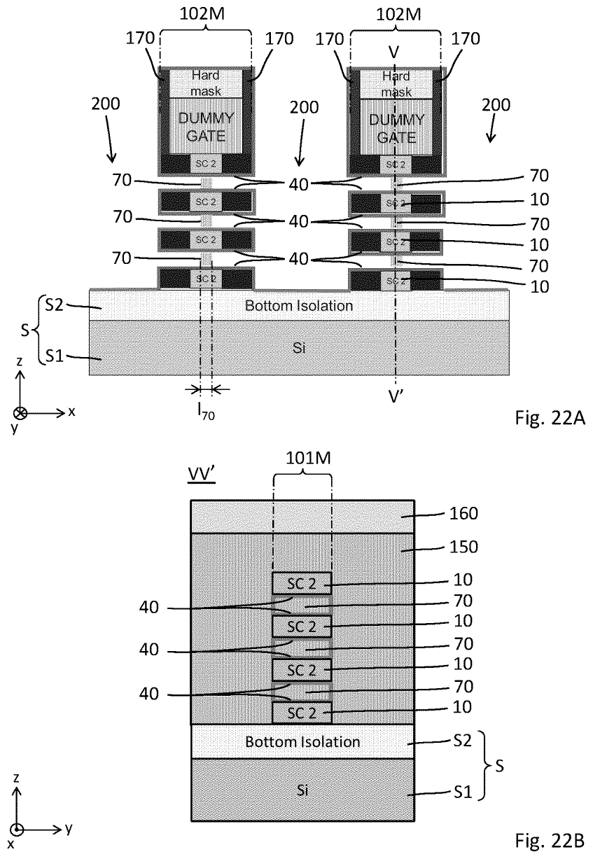

FIGS. 22A, 22B illustrate another example where the isotropic etching is extended, such that the dimension l₇₀ along x of the dielectric plug 70 is less than the dimension l₁₀ along x of the remaining parts of the first layers 10. The edges of the dielectric plug 70 are, in this case, located under the remaining parts of the first layers 10.

By adjusting the parameters of the isotropic etching, in particular, by adjusting the etching time, the dimension l₇₀ along x of the dielectric plug 70 can be accurately controlled, for example, according to the needs or according to the targeted applications. It is possible to produce, on one same chip, different zones comprising devices having different dimensions l₇₀ of dielectric plugs 70. This makes it possible to physically modulate the effective gate length of these devices, according to the zones of the chip.

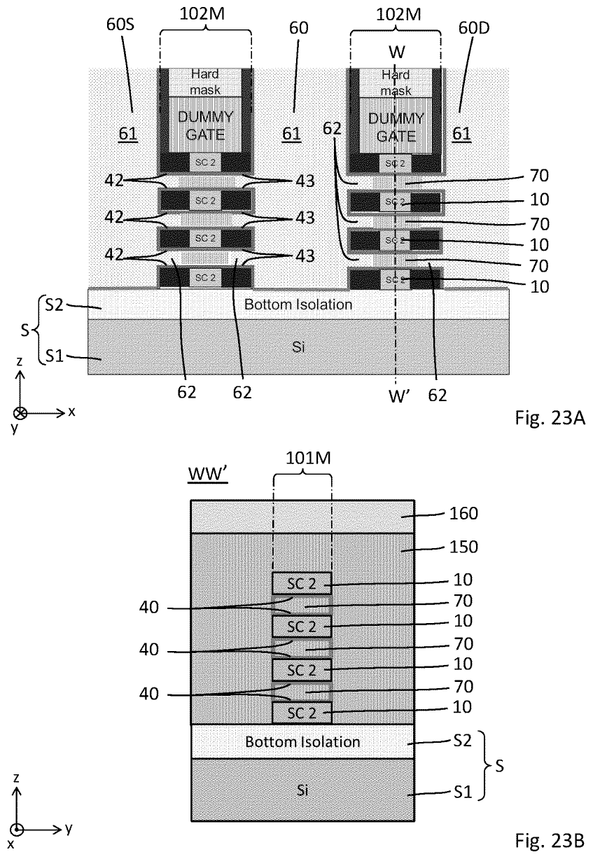

As illustrated in FIGS. 23A, 23B, the second openings 200 are then filled with one or more metal layers, for example, Ti-, TiN, W-based, in order to form the source and drain contacts 60S, 60, 60D, as above. The fingers 62 of the contacts 60S, 60, 60D can be with the basis of a material different from that of the main parts 61 of the contacts 60S, 60, 60D. According to an option, the vertical portions of the layer 40 can be removed before the formation of the contacts 60S, 60, 60D, to avoid a “side” contact as described above in reference to FIGS. 16A, 16B.

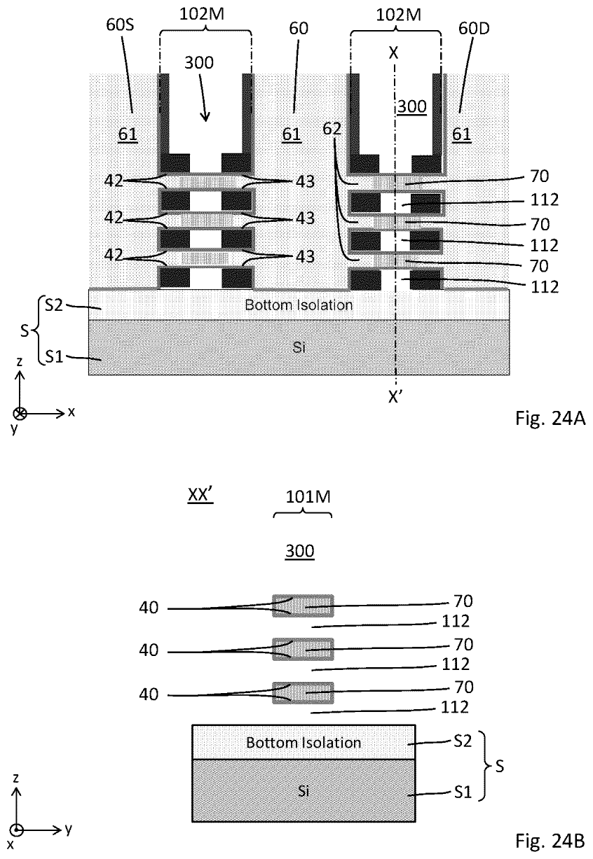

As illustrated in FIGS. 24A, 24B, after formation of the source and drain contacts 60S, 60, 60D, the hard masks 160, the sacrificial gates 150 and the remaining parts of the first layers 10 are successively removed by selective etching, so as to form the third openings 300 and the third spaces 112, as above. The etching has, in particular, a selectivity opposite the first spacers 170, internal spacers 171, of the layer 40 and/or of the inserted dielectric layer.

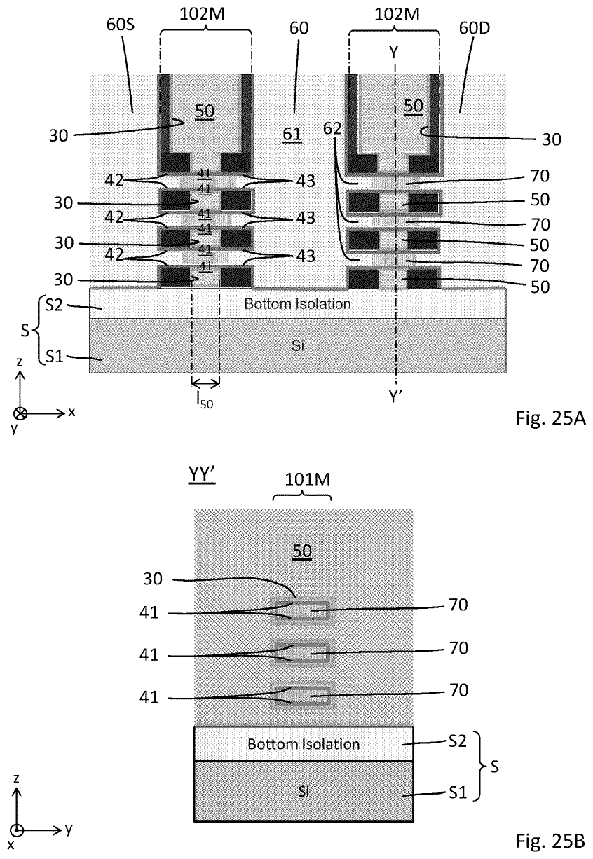

As illustrated in FIGS. 25A, 25B, the gate dielectric layer 30 is first deposited in the third openings 300 and in the third spaces 112, then the gates-all-around 50 of the GAA transistors are formed, as above.

In view of the description above, it clearly appears that the method proposed offers a particularly effective solution to form 2D material-based stacked GAA transistors, comprising source and drain contacts in the form of combs. This solution is further advantageously compatible with standard microelectronics methods. The invention is however not limited to the embodiments described above.

1. A microelectronic device, comprising:
at least two channels stacked along a main direction, each channel being formed with of a semiconductor material,
a gate-all-around, surrounding at least one of the channels over an entire perimeter of said channel,
a source and a drain on either side of the channel, and source and drain contacts connected respectively to the source and to the drain,
a gate dielectric layer separating the channel from the gate-all-around,
spacers on either side of the gate, configured to electrically insulate the gate opposite the source and drain contacts,
wherein the sources and drains each extend in vertical alignment with the spacers along the main direction, and the source and drain contacts each comprise a main part extending along the main direction, and
secondary parts connected to the main part and extending along a sequent direction to the main direction and extending at least partially in vertical alignment with the spacers flanking the gate-all-around, such that the main part and the secondary parts of the source contact form a first comb and the main part and the secondary parts of the drain contact form a second comb opposite the first comb, along the sequent direction.

2. The device according to claim 1, wherein the secondary parts of the source contact and the secondary parts of the drain contact opposite, along the sequent direction, are separated by dielectric plugs.

3. The device according to claim 2, wherein the dielectric plugs further separate two successive stacked channels, along the main direction.

4. The device according to claim 3, wherein the dielectric plugs have a dimension, along the sequent direction, less than a dimension of the gate-all-around at said successive stacked channels, such that the dielectric plugs define an effective gate length shorter than the dimension of the gate-all-around, for the successive stacked channels.

5. The device according to claim 1, wherein each source comprises at least one horizontal portion in contact with a secondary part of the source contact, and wherein each drain comprises at least one horizontal portion in contact with a secondary part of the drain contact.

6. The device according to claim 1, wherein each source comprises a vertical portion in contact with the main part of the source contact, and a horizontal portion in contact with a secondary part of the source contact, and wherein each drain comprises a vertical portion in contact with the main part of the drain contact, and a horizontal portion in contact with a secondary part of the drain contact.

7. The device according to claim 1, wherein each source only comprises a so-called horizontal portion in contact with a secondary part of the source contact, and
wherein each drain only comprises one so-called horizontal portion in contact with a secondary part of the drain contact.

8. The device according to claim 1, wherein the semiconductor material of the channels is taken from among:
transition metal dichalcogenides MX2 with M taken from among molybdenum (Mo) or tungsten (W), and X taken from among sulphur (S), selenium (Se) or tellurium (Te), or
a semiconductor oxide, for example, IGZO (Indium Gallium Zinc Oxide), In₂O₃, IWO (Tungsten Doped Indium Oxide), ITO (Indium Tin Oxide), IAZO (Indium Aluminium Zinc Oxide), InGaZnO, InGaO, InZnO or an amorphous semiconductor oxide, or
graphene, hexagonal boron nitride, or phosphorene.

9. Device The device according to claim 1, wherein the secondary parts of the source and drain contacts are made of a metal material different from the main parts of the source and drain contacts.

10. A method for manufacturing the microelectronic device according to claim 1, said method comprising:
providing, on a substrate, a stack along the main direction comprising first layers made of a first material alternated with second layers made of a second material, the first and second materials being different from the semiconductor material of the channels of the device,
forming, in the stack, first openings defining first patterns,
forming sacrificial gates mounted on the first patterns and partially in the first openings,
forming first spacers on the first patterns and bordering the sacrificial gates,
forming, in the first patterns second openings, defining second patterns,
partially removing, from the second openings the first material of the first layers selectively at the second material of the second layers, so as to form first spaces under the first spacers, and partially under the sacrificial gates,
filling the first spaces with a dielectric material to form internal spacers,
totally removing, from the second openings the second material of the second layers, so as to form second spaces,
depositing a layer with the basis of a semiconductor material on exposed surfaces of the second spaces, without totally filling the second spaces, said layer being to form the semiconductor material-based channels, and the semiconductor material-based sources and drains,
filling the second spaces with a dielectric material, so as to form dielectric plugs occupying the second spaces,
partially etching the dielectric plugs from second openings, on either side of the second patterns so as to reduce a dimension of said dielectric plugs along the sequent direction, the second spaces being obstructed in their centers by the dielectric plugs,
filling the second spaces and the second openings with at least one metal material, so as to form the source and drain contacts in the form of first and second combs opposite one another,
removing the sacrificial gates, so as to form third openings,
totally removing, from the first openings, the first material of the remaining parts of the first layers, so as to form third spaces,
forming called gate dielectric layer in the third spaces, and
filling, with a gate material, the third spaces so as to form the gates-all-around.

11. The method according to claim 10, further comprising, after deposition of the semiconductor material-based layer, a partial removal of partially removing said layer on flanks of the second pattern, substantially parallel to the main direction, on flanks of the first spacers and on flanks of the internal spacers.

12. The method according to claim 10, wherein the partial etching of the dielectric plugs is configured such that the dimension of the dielectric plugs is less than a dimension of the remaining parts of the first layers or than a dimension of the gates-all-around, along the sequent direction.

13. The method according to 12 claim 10, wherein the formation of the gates-all-around is done before the deposition of semiconductor material-based layer.

14. The method according to claim 10, said method comprising, sequenced in the following order:
providing, on the substrate, the stack along the main direction comprising the first layers made of the first material alternated with the second layers made of the second material, the first and second materials being different from the semiconductor material of the channels of the device,
forming, in this the stack, the first openings defining the first patterns,
forming sacrificial gates mounted on the first patterns and partially in the first openings,
forming first spacers on the first pattern and bordering the sacrificial gates,
forming, in the first patterns second openings defining second patterns,
partially removing, from the second openings, the first material of the first layers selectively at the second material of the second layers, so as to form first spaces under the first spacers,
filling the first spaces with a dielectric material to form internal spacers,
filling the second openings with a masking layer,
removing the sacrificial gates, so as to form third openings,
totally removing, from the third openings, the first material of the remaining parts of the first layers, so as to form third spaces,
forming a gate dielectric layer, in the third spaces,
filling, with a material, called gate material, the third spaces, so as to form the gates-all-around,
removing at least partially, the masking layer, so as to form, again, the second openings,
totally removing, from the second openings, the second material of the second layers, so as to form second spaces,
depositing a layer with the basis of a semiconductor material on exposed surfaces of the second spaces, without totally filling the second spaces, said layer being to form the semiconductor material-based channels, and the semiconductor material-based sources and drains,
filling the second spaces with a dielectric material so as to form dielectric plugs occupying the second spaces,
partially etching the dielectric plugs from second openings, on either side of the second patterns, so as to reduce a dimension of said dielectric plugs along the sequent direction, the second spaces being obstructed in their centres by the dielectric plugs, and
filling the second spaces and the second openings with at least one metal material so as to form the source and drain contacts in the form of first and second combs opposite one another.

15. The method according to claim 10, wherein the deposition of the semiconductor material-based layer is done by chemical vapour deposition or by atomic layer deposition.
